(19) United States
(12) Patent Application Publication
(10) Pub. No.: US 2024/0334633 A1
(43) Pub. Date: Oct. 3, 2024

(54) ANALOG CONVERTER BOX MOUNTING STRUCTURE

(71) Applicant: Toyota Motor Engineering & Manufacturing North America, Inc., Plano, TX (US)

(72) Inventor: Nicholas Scott Moody, Westland, MI (US)

(73) Assignee: Toyota Motor Engineering & Manufacturing North America, Inc., Plano, TX (US)

(21) Appl. No.: 18/190,270

(22) Filed: Mar. 27, 2023

(51) Int. Cl. H05K 7/02

(52) U.S. Cl. CPC H05K 7/02

(57) ABSTRACT

A mounting structure for an analog converter box includes a mounting block having a base portion, a block first side wall extending from the base portion, an end wall intersecting the base portion and the block first side wall, and a block first front wall extending from the end wall and the block first side wall so as to overhang a portion of the base portion. The base portion, the block first side wall, the end wall and the block first front wall combine to define a block first pocket structured to receive a portion of the converter box therein. The converter box can be secured to a mounting surface in either of two, orthogonally-related orientations, for the convenience of a user and/or to facilitate testing operations.

### TECHNICAL FIELD

The present invention relates to structures for mounting or securing testing apparatus and, more particularly, to a mounting structure for securing an analog converter box to a mounting surface during testing.

### BACKGROUND

It is frequently necessary to secure an analog converter box to a mounting surface for use in on-road vehicle testing procedures. The converter box must be secured to a mounting surface so as to be immobilized, so that wires can be plugged into (and extracted from) various ports and terminals of the converter box by a user.

Immobilization of the converter box is necessary to avoid damage to equipment and/or personnel during a vehicle collision.

It is often most expedient to use disposable attachment mechanisms (such as Velcro or tie-wraps) to mount the converter box to the mounting surface. It is also frequently necessary to reposition and/or re-orient the converter box during performance of various test procedures. However, with repeated use, Velcro strips loosen and detach from the surfaces to which they are affixed, and the cutting of tie-wraps to reposition the converter box generates a large amount of plastic waste over time.

### SUMMARY

In one aspect of the embodiments described herein, a mounting structure for an analog converter box is provided. The structure includes a mounting block having a base portion, a block first side wall extending from the base portion, an end wall intersecting the base portion and the block first side wall, and a block first front wall extending from the end wall and the block first side wall so as to overhang a portion of the base portion. The base portion, the block first side wall, the end wall and the block first front wall combine to define a block first pocket structured to receive a portion of the converter box therein.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale. Also, unless otherwise stated or shown, the same or similar elements shown in different views may be given the same or similar reference numerals or designations.

FIG. 1 is a schematic perspective view of a mounting structure for an analog converter box in accordance with an embodiment described herein.

FIG. 1A is a schematic cross-sectional side view of the mounting structure shown in FIG. 1.

FIG. 1B is schematic end perspective view of the mounting structure shown in FIG. 1.

FIG. 1C is schematic plan perspective view of the mounting structure shown in FIG. 1.

FIG. 1D is a schematic plan cross-sectional view of an exemplary recess formed at an intersection between a side wall and an end wall of a mounting block in accordance with an embodiment described herein.

FIG. 2 is a schematic front view of an exemplary analog converter box mountable in an embodiment of a mounting structure described herein.

FIG. 3 is schematic front perspective view of the mounting structure shown in FIG. 1, showing an analog converter box mounted therein.

### DETAILED DESCRIPTION

A mounting structure for an analog converter box includes pair of opposable mounting blocks, with each mounting block structured to receive and secure therein an associated end of the converter box. Each block defines a pair of pockets, with each pocket being structured to receive and secure a corner of the converter box therein. When the mounting blocks are secured to a surface (such as a peg board or a rail) in a testing environment and an associated portion of the converter box is received in the pocket, the portion of the converter box is held in a desired position so that the converter box can be used for test purposes. The converter box can be secured to a mounting surface in either of two, orthogonally-related orientations, for the convenience of a user and/or to facilitate testing operations.

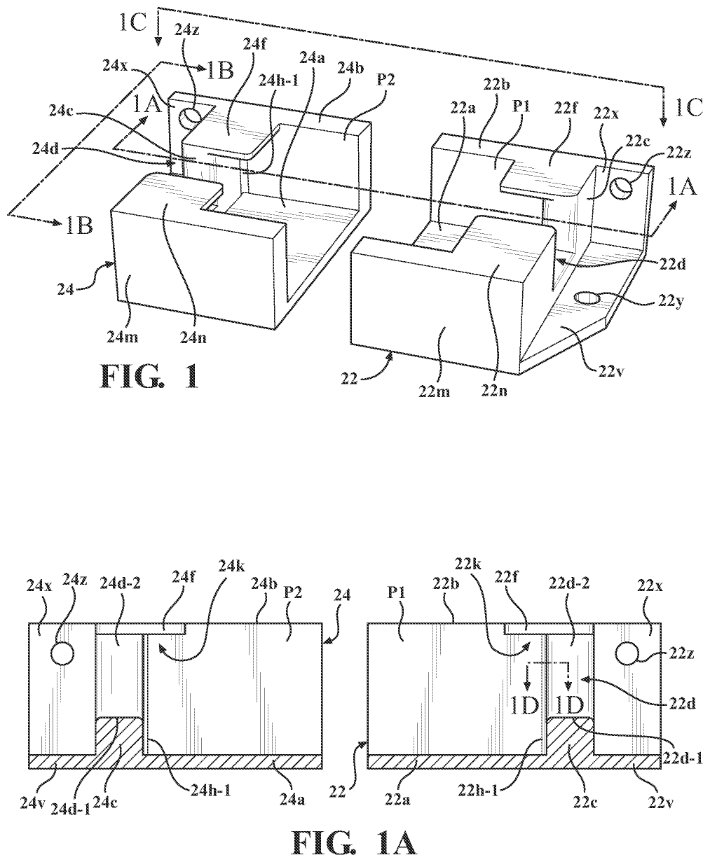

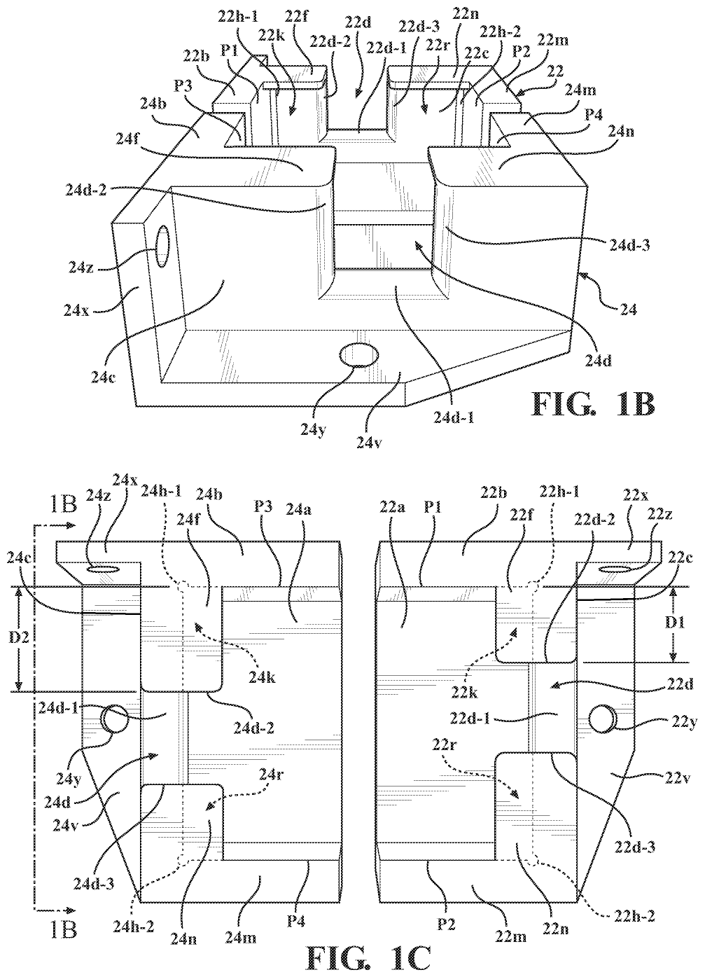

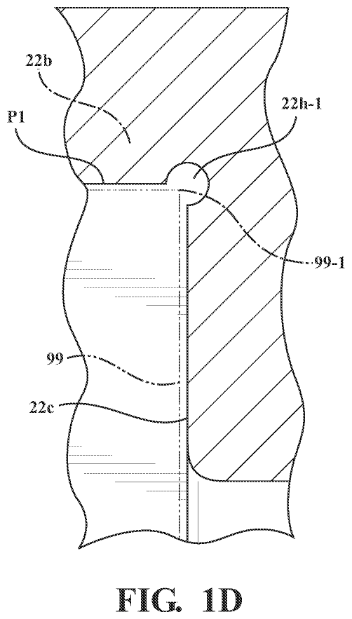

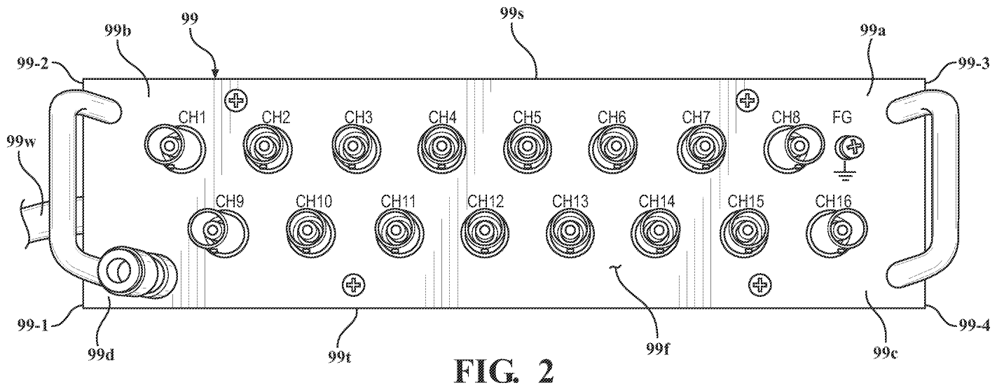

FIG. 1 is a schematic perspective view of a mounting structure for an analog converter box in accordance with an embodiment described herein. FIG. 1A is a schematic cross-sectional side view of the mounting block 22 shown in FIG. 1. FIG. 2 is a schematic front view of an exemplary analog converter box mountable in an embodiment of a mounting structure described herein. Referring to FIGS. 1 and 1A, in one or more arrangements, the mounting structure 20 may include a mounting block 22. The mounting block 22 may have a base portion 22a and a block first side wall 22b extending from the base portion 22a. In one or more arrangements, the block first side wall 22b may define a flat first plane P1. In one or more arrangements, the block first side wall 22b may extend perpendicular to the base portion 22a. An end wall may 22c intersect the base portion 22a and the block first side wall 22b. The end wall 22c may extend perpendicular to the base portion 22a and the block first side wall 22b.

A block first front wall 22f may extend from the end wall 22c and the block first side wall 22b so as to overhang a portion of the base portion 22a. The base portion 22a, the block first side wall 22b, the end wall 22c and the block first front wall 22f may combine to define a block first pocket 22k structured to receive an associated portion of the converter box 99 therein. For a converter box 99 having a rectangular box shape as shown in FIG. 2, the portion of the converter box received in the first pocket may be an exterior corner of the converter box. Each exterior corner may be an intersection of two flat, exterior sides of the box, such as exterior corners 99-1 and 99-2 shown in FIG. 2.

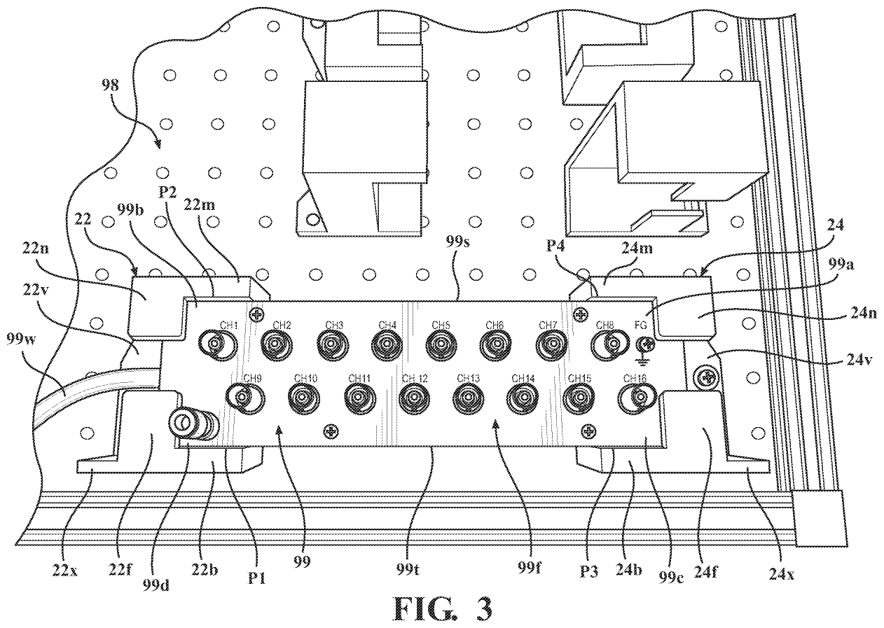

FIG. 1C is schematic plan perspective view of the mounting structure shown in FIG. 1. Referring to FIGS. 1 and 1A-1C, the block end wall 22c may define a block window 22d. The block window 22d may have a first edge 22d-1 extending parallel to the base portion 22a. First edge 22d-1 may be spaced apart a first distance D1 from the plane P1 defined by the block first side wall 22b. The block window 22d may also have a second edge 22d-2 extending from the first edge 22d-1 to the block first front wall 22f, and a third edge 22d-3 extending from the first edge 22d-1 opposite the second edge 22d-2 to a block second front wall 22n (described in greater detail below). The block window 22d may provide a path for wires (such as wires 99w of FIG. 3) leaving the converter box to exit the mounting structure for electrical attachment to a power source, an instrument for processing digital output signals, or another device.

In one or more arrangements, because wires exiting the converter box may contact the edges of the window 22d, all of block window edges 22d-1, 22d-2, and 22d-3 may be curved (i.e., intersections between the edges and other surfaces of the block 22 may be radiused). Providing curved surfaces along the window edges avoids sharp corners which may tend to abrade or fray portions of the wires 99w passing through the window.

FIG. 1D is a schematic cross-sectional view of an exemplary recess 22h-1 formed at an intersection between a side wall (in this case, side wall 22b) and an end wall (in this case, end wall 22c. Referring to FIGS. 1-1D, a block first recess 22h-1 may extend along an intersection of the block first side wall 22b with the end wall 22c. The block first recess 22h-1 may be structured to receive therein a first corner of the portion of the converter box 99 when the portion of the converter box is received in the block first pocket 22k. For example, FIGS. 1D, 2, and 3 illustrate how a corner 99-1 of a converter box 99 (shown in phantom) may be received in recess 22h-1.

Similar recesses may be provided in each of the mounting block pockets described herein. These recesses may prevent corners of the converter box from abutting the intersections between the end walls and adjacent side walls, thereby helping to ensure that exterior sides 99s, 99t of the converter box 99 extending between the corners of the box rest flush against the planes P1, P2, P3, and P4 defined by the side walls 22b, 22m, 24b, and 24m, respectively, when the converter box is received in the mounting blocks 22, 24 as described herein.

Referring to the drawings, in one or more arrangements, the mounting block 22 may further include a block second side wall 22m extending from the base portion 22a opposite the block first side wall 22b. In one or more arrangements, the block second side wall 22m may define a flat second plane P2. In one or more arrangements, the block second side wall 22m may extend perpendicular to the base portion 22a and to the end wall 22c. Also, a block second front wall 22n may extend from the end wall 22c and the block second side wall 22m so as to overhang a portion of the base portion 22a. The base portion 22a, the block second side wall 22m, the end wall 22c and the block second front wall 22n may combine to define a block second pocket 22r structured to receive another associated portion of the converter box therein. In addition, a block second recess 22h-2 may extend along an intersection of the block second side wall 22m with the end wall 22c. Block second recess 22h-2 may be structured to receive therein a corner of another portion of the converter box when the other portion of the converter box is received in the second pocket 22r.

Mounting block 22 may also include a block first mounting flange 22x extending from the block first side wall 22b. Flange 22x may include a mounting hole 22z. Mounting block 22 may also include a block second mounting flange 22v extending from the block end wall 22c so as to orthogonally intersect the block first mounting flange 22x. Flange 22v may include a mounting hole 22y. Mounting flanges 22x and 22v may enable the mounting block 22 to be attached to a mounting surface in either of two orthogonally-related mounting orientations. More specifically, referring to FIG. 3, attachment of the blocks 22 and 24 to a surface 98 using mounting flanges 22v and 24v, respectively, enables the converter box 99 to be secured in position with respect to the surface 98 so that the converter box 99 faces in a direction perpendicular to the surface 98 (i.e., so that a face 99f of the converter box extends parallel to the surface 98). Similarly, attachment of the blocks 22 and 24 to the surface 98 using mounting flanges 22x and 24x, respectively, enables the converter box 99 to be secured in position with respect to the surface 98 so that the converter box 99 faces in a direction parallel to the surface 98 (i.e., so that the face 99f of the converter box extends perpendicular to the mounting surface 98).

Referring again to the drawings, the mounting structure 20 may also include another mounting block 24 separate from the mounting block 22. The other mounting block 24 may include another base portion 24a and another block first side wall 24b extending from the other base portion 24a. In one or more arrangements, the other block first side wall 24b may define another flat first plane P3. In one or more arrangements, the other block first side wall 24b may extend perpendicular to the base portion 24a. In addition, another end wall 24c may intersect the other base portion 24a and the other block first side wall 24b. The other end wall 24c may extend perpendicular to the other base portion 24a and the other block first side wall 24b.

Another block first front wall 24f may extend from the other end wall 24c and the other block first side wall 24b so as to overhang a portion of the other base portion 24a. In addition, the other base portion 24a, the other block first side wall 24b, the other end wall 24c and the other block first front wall 24f may combine to define another block first pocket 24k structured to receive an associated portion of the converter box 99 therein.

Referring again to FIGS. 1 and 1A-1C, the other end wall 24c may define another block window 24d. The other block window 24d may have another first edge 24d-1 extending parallel to the other base portion 24a. The other first edge 24d-1 may be spaced apart a second distance D2 from the plane P2 defined by the other block first side wall 24b. The other block window 22d may also have a second edge 24d-2 extending from the other block window first edge 24d-1 to the other block first front wall 24f, and a third edge 24d-3 extending from the first edge 24d-1 opposite the second edge 24d-2 to the other block second side wall 24m (described in greater detail below).

The other block window 24d may provide a path for wires leaving an end of the converter box 99. Similar to the previously-described block window 22d, because wires exiting the converter box 99 may contact the edges of window 24d, all of other block window edges 24d-1, 24d-2, and 24d-3 may be curved (i.e., intersections between the edges and other surfaces of the block 24 may be radiused).

In addition, in one or more arrangements, with the block end wall 22c spaced apart a first distance D1 from the block first side wall 22b, the other block end wall 24c may be structured so that the other block window first edge 24d-1 is spaced apart a second distance D2 from the other block first side wall 24b, and the second distance D2 may be greater than the first distance D1. This arrangement is designed to accommodate a situation where wires 99w and 99y exit the converter box at different distances from a given side (either side 99s or side 99t) of the converter box.

Referring to the drawings, in one or more arrangements, the other mounting block 24 may further include another block second side wall 24m extending from the base portion 24a opposite the other block first side wall 24b. In one or more arrangements, the other block second side wall 24m may define another block flat second plane P4. In one or more arrangements, the other block second side wall 24m may extend perpendicular to the other base portion 24a and to the other end wall 24c. In addition, another block second front wall 24n may extend from the other end wall 24c and the other block second side wall 24m so as to overhang a portion of the other base portion 24a. The other base portion 24a, the other block second side wall 24m, the other end wall 24c and the other block second front wall 24n may combine to define another block second pocket 24r structured to receive an associated portion of the converter box 99 therein.

Also, another block second recess 24h-2 may extend along an intersection of the other block second side wall 24m with the other end wall 24c. In a manner previously described, other block second recess 24h-2 may be structured to receive therein a corner of the converter box 99 when a portion of the converter box 99 is received in the other block second pocket 24r.

Referring to FIGS. 1C and 3, in one or more arrangements, the block 22 and the other block 24 may be structured so that the block flat first plane P1 and the other block flat first plane P3 are coplanar or substantially coplanar (within a tolerance range of ±0.05 inches inclusive) when the block 22 and the other block 24 are secured in converter-receiving positions with respect to each other. The block 22 and the other block 24 may be considered secured in converter-receiving positions with respect to each other when the blocks 22, 24 are fixed opposite each other as shown in FIG. 3, in positions where portions of the converter box 99 are received in the first and second pockets 22k, 22r of the block 22 and other portions of the converter box 99 are received in the first and second pockets 24k, 24r of the other block 24, with additional, unsupported portions of the converter box 99 extending between the block 22 and the other block 24 so that the converter box 99 is secured in a desired position by the block 22 and the other block 24.

In one or more arrangements, the block 22 and the other block 24 may be structured so that the block flat second plane P2 and the other block flat second plane P4 are coplanar or substantially coplanar (within a tolerance range of ±0.05 inches inclusive) when the block 22 and the other block 24 are secured in converter-receiving positions with respect to each other. Thus, for example, in the arrangement shown in FIG. 3, portion 99a of the converter box 99 is secured in other block second pocket 24r, portion 99b of the converter box 99 is secured in block second pocket 22r, portion 99c of the converter box 99 is secured in other block first pocket 24k, and portion 99d of the converter box 99 is secured in block first pocket 22k, to fix the converter box 99 in position in relation to the mounting surface 98 for operation. In addition, coplanar planes P2 and P4 cooperate to support side 99s of the converter box 99, and coplanar planes P1 and P3 cooperate to support side 99t of the converter box 99.

As described herein, when the mounting block 22 is secured to a surface (such as a peg board or a rail) in a testing environment and an associated portion of the converter box is received in the pocket, the portion of the converter box is held in a desired position so that the converter box can be used for test purposes.

In the above detailed description, reference is made to the accompanying figures, which form a part hereof. In the figures, similar symbols typically identify similar components, unless context dictates otherwise. The illustrative embodiments described in the detailed description, figures, and claims are not meant to be limiting. Other embodiments may be utilized, and other changes may be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e. open language). The phrase “at least one of . . . and . . . ” as used herein refers to and encompasses any and all possible combinations of one or more of the associated listed items. As an example, the phrase “at least one of A, B and C” includes A only, B only, C only, or any combination thereof (e.g. AB, AC, BC or ABC).

Aspects herein can be embodied in other forms without departing from the spirit or essential attributes thereof. Accordingly, reference should be made to the following claims, rather than to the foregoing specification, as indicating the scope of the invention.

1. The mounting structure of claim 16, wherein the mounting block includes:
an end wall intersecting the block first side wall; and
a block first pocket extending between the end wall and the block first side wall,
the end wall intersecting the block first side wall along a block first recess extending into the end wall and the block first side wall in a direction away from the first pocket.

2. The mounting structure of claim 1, wherein the end wall defines the block window.

3. The mounting structure of claim 16, wherein edges of the block window are curved.

4. (canceled)

5. The mounting structure of claim 1, wherein the mounting block further includes:
a block second side wall extending opposite the block first side wall and intersecting the end wall; and
a block second pocket extending between the end wall and the block second side wall,
the end wall intersecting the block second side wall along a block second recess extending into the end wall and the block second side wall in a direction away from the block second pocket.

6. (canceled)

7. The mounting structure of claim 16, wherein the another mounting block includes:
another end wall intersecting the another block first side wall; and
another block first pocket extending between the another end wall and the another block first side wall,
the another end wall intersecting the another block first side wall along another block first recess extending into the another end wall and the another block first side wall in a direction away from the another first pocket.

8. The mounting structure of claim 7, wherein the mounting block and the ether mounting block are structured so that a flat first plane defined by the block first side wall and another flat first plane defined by the another block first side wall are coplanar or substantially coplanar when the block and the another block are secured in converter box-receiving positions with respect to each other.

9. The mounting structure of claim 7, wherein the another end wall defines the another block window.

10. The mounting structure of claim 16, wherein edges of the another block window are curved.

11. (canceled)

12. The mounting structure of claim 7, wherein the another mounting block further includes:
another block second side wall extending opposite the another block first side wall and intersecting the end wall; and
another block second pocket extending between the another end wall and the another block second side wall,
the another end wall intersecting the another block second side wall along another block second recess extending into the another end wall and the another block second side wall in a direction away from the another block second pocket.

13. (canceled)

14. (canceled)

15. (canceled)

16. A mounting structure for an analog converter box, the mounting structure comprising:
a mounting block having:
a block first side wall defining a flat first plane; and
a block window spaced apart a first distance from the flat first plane;
another mounting block separate from the mounting block and having:
a block second side wall defining a flat second plane; and
another block window spaced apart a second distance from the flat second plane, wherein the second distance is greater than the first distance.

17. The mounting structure of claim 16, wherein the mounting block and the another mounting block are structured so that the flat first plane and the flat second plane are coplanar or substantially coplanar when the block and the another block are secured in converter box-receiving positions with respect to each other.
